(19) United States
(12) Patent Application Publication
(10) Pub. No.: US 2026/0090154 A1
(43) Pub. Date: Mar. 26, 2026

(54) LIGHT EMITTING ELEMENT AND METHOD FOR MANUFACTURING THE SAME

(71) Applicant: LG Display Co., Ltd., Seoul (KR)

(72) Inventors: Yuseop SHIN, Bucheon-si (KR); Kiyong HONG, Paju-si (KR); Kiyoung SONG, Paju-si (KR); Jinhyeon YUN, Paju-si (KR); Jihyun KOO, Seoul (KR); Byungyeon CHOI, Goyang-si (KR)

(73) Assignee: LG Display Co., Ltd., Seoul (KR)

(21) Appl. No.: 19/284,473

(22) Filed: Jul. 29, 2025

(30) Foreign Application Priority Data
Sep. 24, 2024 (KR) 10-2024-0129215

(51) Int. Cl. H10H 20/855; H01L 25/075; H10H 20/01; H10H 20/80; H10H 20/831

(52) U.S. Cl. CPC H10H 20/855; H10H 20/032; H10H 20/0363; H10H 20/8312; H10H 20/882; H10W 90/00

(57) ABSTRACT

A light emitting element and a method for manufacturing the light emitting element are provided. The method includes forming an epi layer with a plurality of grooves on a wafer, forming a plurality of assembly lines on the epi layer, self-assembling a plurality of light extraction particles into the grooves by applying a voltage to the assembly lines, and forming a plurality of light emitting elements by etching the assembly lines and the epi layer. The light extraction particles, which may include magnetic cores and scattering materials, are positioned using an electric field through dielectrophoresis. This self-assembly process enables precise placement of the light extraction particles within each groove and allows simultaneous formation across multiple devices. By integrating the light extraction members during fabrication and reusing the assembly lines as electrodes, the method simplifies processing, enhances uniformity of light emission, and improves luminance performance across various viewing angles.

### CROSS-REFERENCE TO RELATED APPLICATIONS

This application claims the priority of Korean Patent Application No. 10-2024-0129215 filed on Sep. 24, 2024, in the Korean Intellectual Property Office, the disclosure of which is incorporated herein by reference.

### BACKGROUND

### Technical Field

The present disclosure relates to a light emitting element and a method for manufacturing the light emitting element, and more particularly, to a method for manufacturing a light emitting diode (LED) and a display device including the same.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

The disclosed subject matter relates to a method for manufacturing light emitting elements such as micro light emitting diodes by assembling light extraction particles into grooves formed in a semiconductor layer (e.g., a second semiconductor layer 123) of the device. This assembly is achieved using an electric field generated by a pair of patterned electrodes referred to as assembly lines, which are subsequently retained as functional electrodes within the final device structure. This approach enables simultaneous positioning of the particles across multiple devices while reducing the number of process steps.

The process employs composite particles that include magnetic cores with scattering materials coated on their surfaces. These particles may be guided using both electric and magnetic fields. In certain embodiments, the particles are dispersed in a resin to form a micro lens structure that enhances light extraction in the forward direction and reduces luminance variation with respect to the viewing angle. The approach is adaptable to both lateral and vertical light emitting diode configurations, allowing broader applicability in different device architectures.

By integrating the light extraction features during the fabrication process through electrically assisted assembly, the described method enhances both luminous efficiency and viewing angle performance. The reuse of the same electrodes for particle assembly and for subsequent device operation simplifies processing. Additional features such as dielectric coatings and resin based lens structures further support performance improvements while maintaining compatibility with high volume manufacturing.

Various embodiments of the present disclosure provide a method for manufacturing a light emitting element with improved luminous efficiency.

Various embodiments of the present disclosure provide a method for manufacturing a light emitting element with an improved luminance deviation according to a viewing angle.

Various embodiments of the present disclosure provide a method for manufacturing a light emitting element which scatters light to reduce a luminance difference in a front direction and a lateral direction.

Various embodiments of the present disclosure provide a method for manufacturing a light emitting element which easily forms a plurality of light extraction particles by a self-assembly manner.

Various embodiments of the present disclosure provide a method for manufacturing a light emitting element which places the light extraction member in the light emitting element by a self-assembly method to simplify the process.

Various embodiments of the present disclosure provide a method for manufacturing a light emitting element which simultaneously self-assembles a light extraction member in each of the plurality of light emitting elements using an electric field to achieve the process optimization.

Technical benefits of the present disclosure are not limited to the above-mentioned benefits, and other benefits, which are not mentioned above, can be clearly understood by those skilled in the art from the following descriptions.

According to an aspect of the present disclosure, a method for manufacturing a light emitting element includes a step of forming an epi layer having a plurality of grooves on a wafer, a step of forming a plurality of assembly lines on the epi layer, a step of self-assembling a plurality of light extraction particles in each of the plurality of grooves by applying a voltage to the plurality of assembly lines, and a step of forming a plurality of light emitting elements by etching the plurality of assembly lines and the epi layer. Accordingly, the plurality of light extraction particles may be easily disposed in the light emitting element by the self-assembly method using an electric field and the process may be simplified.

According to an aspect of the present disclosure, a light emitting element includes a first semiconductor layer, an emission layer on the first semiconductor layer, a second semiconductor layer which is disposed on the emission layer and has one or more grooves therein, a first electrode which is in contact with the first semiconductor layer, one pair of second electrodes disposed on a top surface of the second semiconductor layer, and a light extraction member disposed in the groove. Accordingly, the light extraction member is formed in the light emitting element to reduce the luminance difference in the front direction and the lateral direction of the light emitting element.

Other detailed matters of the exemplary embodiments are included in the detailed description and the drawings.

According to the present disclosure, a method for manufacturing a light emitting element with an excellent luminance efficiency may be provided.

According to the present disclosure, the luminance deviation of the light emitting element according to the viewing angle may be improved.

According to the present disclosure, the light of the light emitting element is scattered to reduce the luminance difference in the front direction and the lateral direction.

According to the present disclosure, a plurality of light extraction particles may be easily formed by the self-assembly method.

According to the present disclosure, the light extraction member is formed in the light emitting element by the self-assembly method to shorten the process time.

According to the present disclosure, the light extraction members are simultaneously self-assembled in the plurality of light emitting elements using an electric field to achieve the process optimization.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a sub pixel of a display device according to an exemplary embodiment of the present disclosure;

FIG. 4 is a cross-sectional view of a sub pixel of a display device according to an exemplary embodiment of the present disclosure;

FIG. 5 is a graph illustrating a luminance according to a viewing angle of a light emitting element according to a comparative embodiment and an exemplary embodiment;

FIGS. 6A to 10B are process diagrams for explaining a method for manufacturing a light emitting element according to an exemplary embodiment of the present disclosure;

FIG. 11 is an enlarged cross-sectional view of a light emitting element of a display device according to another exemplary embodiment of the present disclosure;

FIG. 12 is an enlarged cross-sectional view of a light emitting element of a display device according to still another exemplary embodiment of the present disclosure; and

FIG. 13 is an enlarged cross-sectional view of a light emitting element of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, the layer or element may be disposed directly on another element or layer, or the other element may be interposed therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

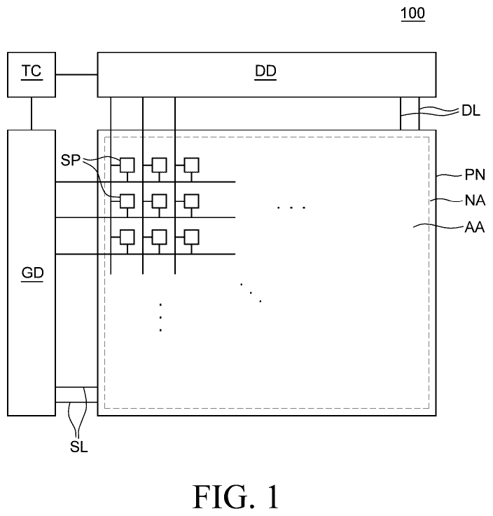

FIG. 1 is a schematic diagram of a display device according to an exemplary embodiment of the present disclosure. In FIG. 1, for the convenience of description, among various components of the display device, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD may convert the image data into a data voltage using a reference gamma voltage and supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP may be formed at intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configures a plurality of pixels PX and a pixel circuit for driving the plurality of sub pixels SP may be disposed. The plurality of sub pixels SP is a minimum unit which configures the active area AA and n sub pixels SP may form one pixel PX. In each of the plurality of sub pixels SP, a thin film transistor for driving the plurality of light emitting elements 120 may be disposed. The plurality of light emitting elements 120 may be defined in different ways depending on the type of the display panel PN. For example, when the display panel PN is an inorganic light emitting display panel PN, the light emitting element 120 may be a light emitting diode (LED) or a micro light emitting diode (micro LED).

In the active area AA, a plurality of signal lines which transmits various signals to the plurality of sub pixels SP is disposed. For example, the plurality of signal lines may include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN may be electrically connected to the data driver DD and the timing controller TC by bonding the flexible film and the printed circuit board to the pad electrode formed in the non-active area NA of the display panel PN.

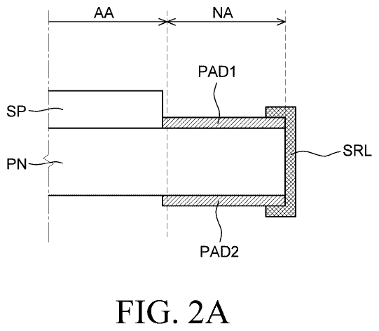

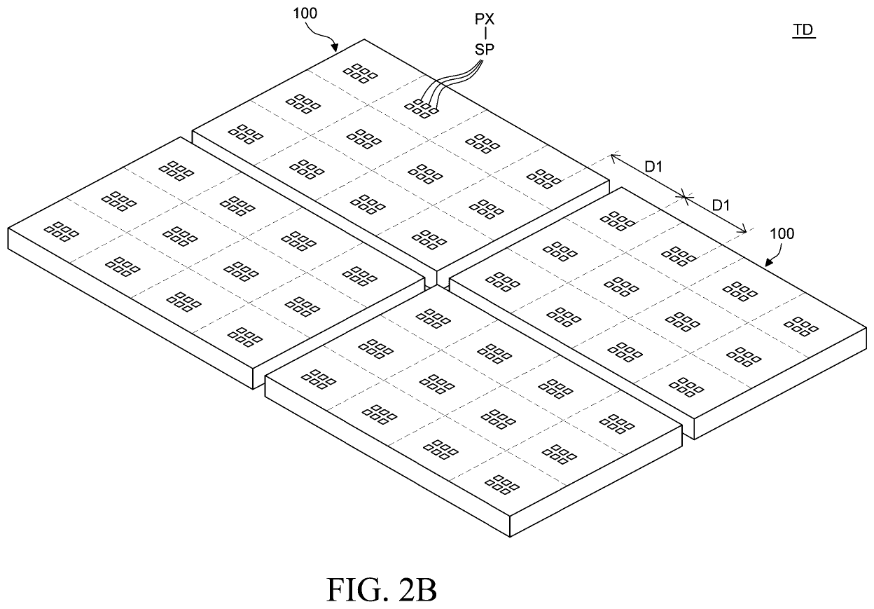

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA on the front surface of the display panel PN may be minimized. Therefore, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signaling pathway is formed from the front surface of the display panel PN to the side surface and the rear surface to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2B, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the interval of the pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

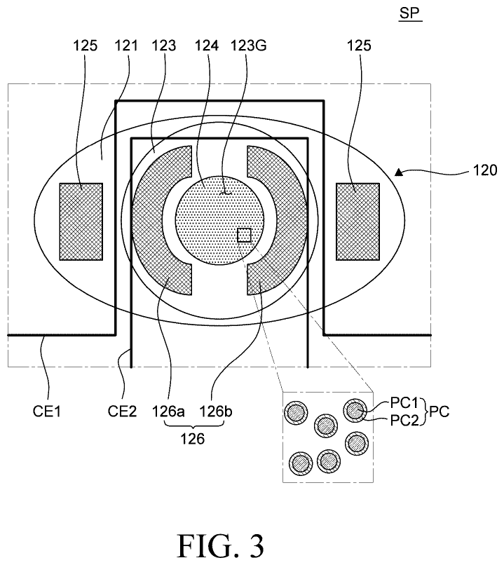

Hereinafter, a sub pixel SP of a display panel PN of a display device 100 according to an exemplary embodiment of the present disclosure will be described in more detail with reference to FIGS. 3 to 5.

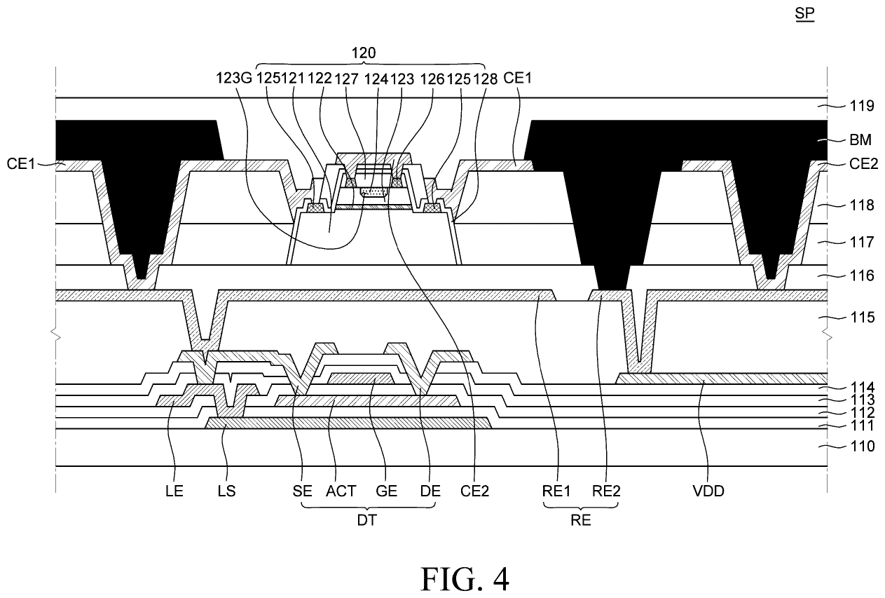

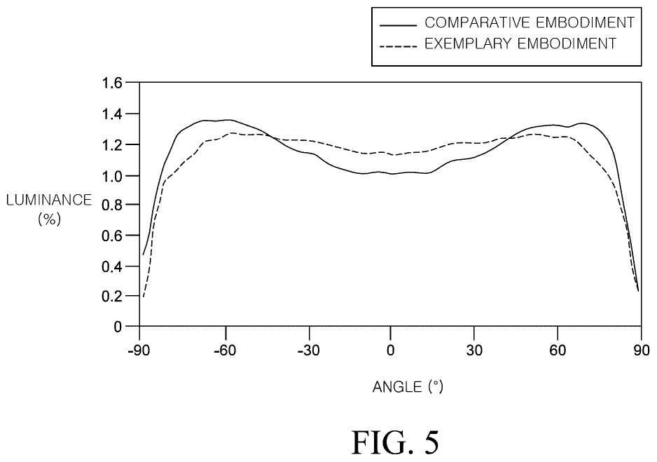

FIG. 3 is a plan view of a sub pixel of a display device according to an exemplary embodiment of the present disclosure. FIG. 4 is a cross-sectional view of a sub pixel of a display device according to an exemplary embodiment of the present disclosure. FIG. 5 is a graph illustrating a luminance according to a viewing angle of a light emitting element according to a comparative embodiment and an exemplary embodiment. In FIG. 3, for the convenience of illustration, only the light emitting element 120, the first connection electrode CE1, and the second connection electrode CE2 are illustrated.

Referring to FIGS. 3 and 4, the substrate 110 may be a member which supports other components of the display device 100 and may be an insulating substrate 110. For example, the substrate 110 may be formed of glass or resin. Further, the substrate 110 may be formed of polymer or plastic and in some exemplary embodiments, the substrate 110 may be formed of a plastic material having flexibility. A plurality of pixels PX each including a plurality of sub pixels SP is formed on the substrate 110 to display images.

A light shielding layer LS is disposed on the substrate 110 in each of the plurality of sub pixels SP. The light shielding layer LS blocks light which is incident onto the active layer ACT of the driving transistor DT to minimize a leakage current. For example, the light shielding layer LS is disposed below the active layer ACT of the driving transistor DT to block light incident onto the active layer ACT. If light is irradiated onto the active layer ACT, the leakage current is generated, which may degrade the reliability of the driving transistor DT. Accordingly, the light shielding layer LS which blocks the light is disposed on the substrate 110 to improve the reliability of the driving transistor DT. The light shielding layer LS may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the substrate 110 and the light shielding layer LS. The buffer layer 111 is disposed so as to cover one surface of the substrate 110 to reduce permeation of moisture or impurities through the substrate 110. For example, the buffer layer 111 may be configured by a single layer or a double layer of silicon oxide (SiOx) or silicon nitride (SiNx), but is not limited thereto. The buffer layer 111 may be omitted depending on a type of substrate 110 or a type of transistor, but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. In the meantime, even though it is not illustrated in the drawing, in each of the plurality of sub pixels SP, other components, such as a switching transistor, a sensing transistor, an emission control transistor, and a storage capacitor may be further disposed, in addition to the driving transistor DT.

The active layer ACT of the driving transistor DT is disposed on the buffer layer 111. The active layer ACT may be disposed so as to overlap the light shielding layer LS. The active layer ACT may be formed of a semiconductor material, such as an oxide semiconductor, amorphous silicon, or polysilicon, but is not limited thereto. Further, even though it is not illustrated in the drawings, active layers ACT of another transistors, such as a switching transistor, a sensing transistor, and an emission control transistor, may also be formed of a semiconductor material, such as an oxide semiconductor, amorphous silicon, or polysilicon, but are not limited thereto. The active layers ACT of the driving transistor DT, the switching transistor, the sensing transistor, and the emission control transistor may be formed of the same material, or formed of different materials.

The gate insulating layer 112 is disposed on the active layer ACT. The gate insulating layer 112 is an insulating layer for insulating the active layer ACT from the gate electrode GE. For example, the gate insulating layer 112 may be configured by a single layer or a double layer of silicon oxide (SiOx) or silicon nitride (SiNx), but is not limited thereto. In the meantime, even though in the drawing, it is illustrated that the gate insulating layer 112 is disposed only below the gate electrode GE, the gate insulating layer 112 may be disposed on the front surface of the substrate 110, but is not limited thereto.

The gate electrode GE is disposed on the gate insulating layer 112. The gate electrode GE may be disposed so as to overlap the active layer ACT. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT are formed. The first interlayer insulating layer 113 and the second interlayer insulating layer 114 are insulating layers which protect components therebelow and may be configured by single layers or double layers of silicon oxide (SiOx) or silicon nitride (SiNx), but are not limited thereto.

The source electrode SE and the drain electrode DE are disposed on the second interlayer insulating layer 114. The source electrode SE and the drain electrode DE may be electrically connected to the active layer ACT through contact holes formed in the first interlayer insulating layer 113, the second interlayer insulating layer 114, and the gate insulating layer 112. Any one of the source electrode SE and the drain electrode DE may be electrically connected to the light emitting element 120. For example, any one of the source electrode SE and the drain electrode DE may supply a driving current to the light emitting element 120 through a first connection electrode CE1 and a first reflective electrode REL. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

An auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized. Even though in the drawing, it is illustrated that the light shielding layer LS is connected to the source electrode SE, the light shielding layer LS may also be connected to the drain electrode DE, but is not limited thereto.

The power line VDD is disposed on the second interlayer insulating layer 114. The power line VDD may be configured to transmit a power voltage to the light emitting elements 120 of the plurality of sub pixels SP. The power line VDD may supply any one of a high potential power voltage or a low potential power voltage according to the configuration of the pixel circuit. The power line VDD may be configured by a conductive material, such as copper (Cu), aluminum (Al), molybdenum (Mo), nickel (Ni), titanium (Ti), chrome (Cr), or an alloy thereof, but is not limited thereto.

A first planarization layer 115 is disposed on the driving transistor DT, the power line VDD, and the second interlayer insulating layer 114. The first planarization layer 115 may planarize an upper portion of the pixel circuit including the driving transistor DT. The first planarization layer 115 may be configured by a single layer or a double layer, and for example, configured by benzocyclobutene or an acrylic organic material, but is not limited thereto.

A plurality of reflective electrodes RE which is spaced apart from each other is disposed on the first planarization layer 115. The plurality of reflective electrodes RE may electrically connect the light emitting element 120 to the power line VDD and the driving transistor DT and serve as a reflector which reflects light emitted from the light emitting element 120 to the upper portion of the light emitting element 120. The plurality of reflective electrodes RE is formed of a conductive material having excellent reflecting property to reflect light emitted from the light emitting element 120 toward the upper portion of the light emitting element 120. For example, the plurality of reflective electrodes RE may include a conductive material having excellent reflecting property, such as silver (Ag) or aluminum (Al). Further, the plurality of reflective electrodes RE may further include a transparent conductive layer, such as indium tin oxide (ITO) in consideration of resistance, but is not limited thereto.

The plurality of reflective electrodes RE includes a first reflective electrode RE1 and a second reflective electrode RE2. The first reflective electrodes RE1 may electrically connect the driving transistor DT and the light emitting element 120. The first reflective electrode RE1 may be connected to the source electrode SE or the drain electrode DE of the driving transistor DT through a contact hole formed in the first planarization layer 115. The first reflective electrode RE1 may be electrically connected to the first electrode 125 and the first semiconductor layer 121 of the light emitting element 120 through a first connection electrode CE1 to be described below.

The second reflective electrode RE2 may electrically connect the power line VDD and the light emitting element 120. The second reflective electrode RE2 may be connected to the power line VDD through a contact hole formed in the first planarization layer 115 and may be electrically connected to a second electrode 126 and a second semiconductor layer 123 of the light emitting element 120 through a second connection electrode CE2 to be described below.

An adhesive layer 116 is disposed on the plurality of reflective electrodes RE. The adhesive layer 116 is coated on the front surface of the substrate 110 to fix the light emitting element 120 disposed on the adhesive layer 116. For example, the adhesive layer 116 may be selected from any one of adhesive polymer, epoxy resin, UV resin, polyimide, acrylate, urethane, and polydimethylsiloxane (PDMS), but is not limited thereto.

The plurality of light emitting elements 120 is disposed in each of the plurality of sub pixels SP on the adhesive layer 116. The plurality of light emitting elements 120 is an element which emits light by a current and may include a light emitting element 120 which emits red light, green light, and blue light and may implement various colored lights including white by a combination thereof. For example, the plurality of light emitting elements 120 may be a light emitting diode (LED) or a micro LED, but is not limited thereto.

The light emitting element 120 includes a first semiconductor layer 121, an emission layer 122, a second semiconductor layer 123, a first electrode 125, a second electrode 126, a light extraction member 124, a first protection film 127, and a second protection film 128.

The first semiconductor layer 121 is disposed on the adhesive layer 116 and the second semiconductor layer 123 is disposed on the first semiconductor layer 121. The first semiconductor layer 121 and the second semiconductor layer 123 may be semiconductor layers doped with n-type and p-type impurities. For example, the first semiconductor layer 121 and the second semiconductor layer 123 may be layers formed by doping p-type and n-type impurities into a material, such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium (Ge), and tin (Sn), but are not limited thereto.

The emission layer 122 is disposed between the first semiconductor layer 121 and the second semiconductor layer 123. The emission layer 122 may emit light based on a driving current supplied to the light emitting element 120. For example, the emission layer 122 may be configured as a single layer or a multi-quantum well (MQW) structure. For example, the emission layer 122 may be configured by indium gallium nitride (InGaN) or gallium nitride (GaN), but it is not limited thereto.

A groove 123G is formed in the second semiconductor layer 123 and the light extraction member 124 is disposed in the groove 123G. The light extraction member 124 is a member which scatters and extracts light emitted from the emission layer 122 and may uniformly extract the light in the front direction and the lateral direction of the light emitting element 120. The groove 123G of the second semiconductor layer 123 extends from the top surface of the second semiconductor layer 123 toward the emission layer 122. The light extraction member 124 is disposed in the groove 123G of the second semiconductor layer 123 to overlap the emission layer 122. The groove 123G and the light extraction member 124 are disposed in the second semiconductor layer 123 so as not to be in direct contact with the emission layer 122.

The light extraction member 124 may be formed of a plurality of light extraction particles PC. The plurality of light extraction particles PC may be formed of magnetic particles PC1 coated with the scattering particles PC2 at the outside. For example, the magnetic particles PC1 of the plurality of light extraction particles PC may be formed of ferromagnetic particles, ferrimagnetic particles, a transition metal such as iron (Fe), cobalt (Co), or nickel (Ni), oxide including a transition metal, and a metal compound including rare-earth atoms such as neodymium (Nd) or samarium (Sm), but is not limited thereto. The scattering particles PC2 coated on a surface of the magnetic particles PC1 may include titanium oxide (TiO₂), zirconium oxide (ZrO₂), or barium titanate (BaTiO₃), but are not limited thereto.

The first electrode 125 is disposed on the first semiconductor layer 121. The first semiconductor layer 121 may include a part protruding from the emission layer 122 and the second semiconductor layer 123 and one or more first electrodes 125 may be disposed on the protruding part of the first semiconductor layer 121. For example, one pair of first electrodes 125 may be disposed on the first semiconductor layer 121. The first electrode 125 may be in contact with the top surface of the first semiconductor layer 121. The first electrode 125 is an electrode for electrically connecting the light emitting element 120 to the driving transistor DT. The light emitting element 120 may be electrically connected to the driving transistor DT through the first electrode 125, the first reflective electrode RE1, and the first connection electrode CE1. The first electrode 125 may be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The second electrode 126 is disposed on the second semiconductor layer 123. The second electrode 126 may include a 2-1-th electrode 126a and a 2-2-th electrode 126b. The 2-1-th electrode 126a and the 2-2-th electrode 126b may be in contact with the top surface of the second semiconductor layer 123. The 2-1-th electrode 126a and the 2-2-th electrode 126b may be spaced apart from each other with the groove 123G therebetween. The 2-1-th electrode 126a and the 2-2-th electrode 126b are electrodes for self-assembling the plurality of light extraction particles PC in the groove 123G and electrically connecting the light emitting element 120 to the power line VDD. The light emitting element 120 may be electrically connected to the power line VDD through the second electrode 126, the second reflective electrode RE2, and the second connection electrode CE2. The second electrode 126 may be formed of a transparent conductive material, such as indium tin oxide (ITO) or indium zinc oxide (IZO), but is not limited thereto.

The first protection film 127 is disposed to cover the light extraction member 124. The first protection film 127 may cover the light extraction member 124, the second semiconductor layer 123, and the second electrode 126. The first protection film 127 may protect the light extraction member 124 including the plurality of light extraction particles PC. The first protection film 127 may be formed of an insulating material, such as silicon oxide (SiOx) or silicon nitride (SiNx), but is not limited thereto.

The second protection film 128, which encloses the first semiconductor layer 121, the emission layer 122, and the second semiconductor layer 123 is disposed. The second protection film 128 may protect the first semiconductor layer 121, the emission layer 122, and the second semiconductor layer 123. The second protection film 128 may be disposed so as to enclose a side surface of the first semiconductor layer 121, a top surface of the first semiconductor layer 121 on which the first electrode 125 is disposed, a side surface of the emission layer 122, a side surface of the second semiconductor layer 123, and the top surface of the second semiconductor layer 123 on which the first protection film 127 and the second electrode 126 are disposed. The first electrode 125 and the second electrode 126 are exposed from the first protection film 127 and the second protection film 128 to be connected to the first connection electrode CE1 and the second connection electrode CE2. For example, the second protection film 128 may be formed of an insulating material, such as silicon oxide (SiOx) or silicon nitride (SiNx), but is not limited thereto.

Next, the second planarization layer 117 and the third planarization layer 118 which enclose the light emitting element 120 are disposed on the adhesive layer 116. The second planarization layer 117 overlaps a part of side surfaces of the plurality of light emitting elements 120 to fix and protect the plurality of light emitting elements 120. A part of the side surface of the first semiconductor layer 121 may be exposed from the second protection film 128. The light emitting element 120 manufactured on a wafer is separated from the wafer to be transferred onto the display panel PN. However, during the process of separating the light emitting element 120 from the wafer, a part of the second protection film 128 may be torn. For example, a part of the second protection film 128 which is adjacent to a lower edge of the first semiconductor layer 121 is torn during the process of separating the light emitting element 120 from the wafer so that a part of a lower side surface of the first semiconductor layer 121 may be exposed to the outside. However, even though the lower portion of the light emitting element 120 is exposed from the second protection film 128, the first connection electrode CE11 and the second connection electrode CE2 are formed after forming the second planarization layer 117 which covers the side surface of the first semiconductor layer 121. Accordingly, a short-circuit defect may be minimized.

The third planarization layer 118 is formed to cover upper portions of the second planarization layer 117 and the light emitting element 120 and a contact hole which exposes the first electrode 125 and the second electrode 126 of the light emitting element 120 may be formed. The first electrode 125 and the second electrode 126 of the light emitting element 120 are exposed from the third planarization layer 118 and the third planarization layer 118 is partially disposed in an area between the first electrode 125 and the second electrode 126 to minimize a short-circuit defect.

The second planarization layer 117 and the third planarization layer 118 may be configured by a single layer or a double layer, and for example, may be formed of photo resist or an acrylic organic material, but are not limited thereto. Even though in the present disclosure, it is described that the second planarization layer 117 and the third planarization layer 118 are disposed, the planarization layer may be formed by a single layer, but is not limited thereto.

A plurality of connection electrodes is disposed on the third planarization layer 118. The plurality of connection electrodes includes a first connection electrode CE1 and a second connection electrode CE2.

The first connection electrode CE1 is an electrode which is disposed in each of the plurality of sub pixels SP to electrically connect the light emitting element 120 and the driving transistor DT. The first connection electrode CE1 may be connected to the first reflective electrode RE1 through the contact hole formed in the third planarization layer 118, the second planarization layer 117, and the adhesive layer 116. Accordingly, the first connection electrode CE1 may be electrically connected to any one of the source electrode SE and the drain electrode DE of the driving transistor DT through the first reflective electrode RE1. The first connection electrode CE1 may be connected to the first electrodes 125 of each of the plurality of light emitting elements 120 through a contact hole formed in the third planarization layer 118. Accordingly, the first connection electrode CE1 may electrically connect the driving transistor DT to the first electrode 125 and the first semiconductor layer 121 of the plurality of light emitting elements 120.

The second connection electrode CE2 is an electrode for electrically connecting the light emitting element 120 and the power line VDD. The second connection electrode CE2 may be connected to the second reflective electrode RE2 through the contact hole formed in the third planarization layer 118, the second planarization layer 117, and the adhesive layer 116. Accordingly, the second connection electrode CE2 may be electrically connected to the power line VDD through the second reflective electrode RE2. The second connection electrode CE2 may be connected to the second electrodes 126 of the plurality of light emitting elements 120 through a contact hole formed in the third planarization layer 118. Accordingly, the second connection electrode CE2 may electrically connect the power line VDD to the second electrode 126 and the second semiconductor layer 123 of the plurality of light emitting elements 120.

A black matrix BM is disposed on the plurality of connection electrodes. The black matrix BM may be disposed in a region between the plurality of sub pixels SP. The black matrix BM may reduce external light reflection and suppress color mixture between the plurality of sub pixels SP. The black matrix BM may be formed of an opaque material. For example, the black matrix BM may include a black component and may be formed of an opaque resin including a dye, but is not limited thereto.

A protection layer 119 is disposed on the black matrix BM. The protection layer 119 is a layer for protecting a configuration below the protection layer 119 and may suppress the permeation of moisture or oxygen from the outside. For example, the protection layer 119 may be configured by a single layer or a double layer and for example, may use an epoxy or acryl-based polymer, but is not limited thereto.

In the meantime, as described above, the light emitting element 120 of the display device 100 according to the exemplary embodiment of the present disclosure includes a light extraction member 124 to improve luminance and a viewing angle characteristic. In the light emitting element 120 which is a micro LED, an amount of light directed to a direction slanted to one surface of the emission layer 122 is relatively larger than an amount of light which is directed to a direction perpendicular to one surface of the emission layer 122, that is, a front direction of the display device 100. Therefore, in the display device 100 including the light emitting element 120 which is a micro LED, a front luminance may be relatively lower than a luminance in a lateral direction so that the luminance uniformity according to the viewing angle may be low. At this time, the light extraction member 124 which is disposed above the emission layer 122 scatters and reflects light emitted from the emission layer 122 to uniformly disperse the light and reduce the difference of the amount of light extracted to the front direction and the amount of light extracted to the lateral direction. Accordingly, the luminance difference in the front direction and the lateral direction of the display device 100 may be reduced by the light extraction member 124 of the light emitting element 120 and the luminance deviation according to the viewing angle may be improved.

Hereinafter, a luminance deviation improvement effect of the light extraction member 124 of the light emitting element 120 according to the exemplary embodiment of the present disclosure will be described with reference to FIG. 5.

FIG. 5 is a graph obtained by measuring a luminance according to an angle in each of the light emitting element according to the comparative embodiment and the light emitting element according to the exemplary embodiment. The light emitting element according to the exemplary embodiment has substantially the same structure as the light emitting element 120 of the display device 100 according to the exemplary embodiment of the present disclosure. The light emitting element according to the comparative embodiment is substantially the same as the light emitting element according to the exemplary embodiment except that the groove 123G and the light extraction member 124 are not included.

As a luminance measurement result of the light emitting element according to the comparative embodiment, it is confirmed that the luminance is increased as it is directed to the inclined direction from 0 degrees corresponding to the front direction. For example, it is confirmed that the larger the angle from 0 degrees, the higher the luminance and the luminance is maximum at approximately 60 degrees. For example, when the luminance in the front direction is defined as 100%, a peak luminance in the lateral direction as compared with the luminance in the front direction may be approximately 135%. Therefore, there is a difference between the luminance in the front direction and the luminance in the lateral direction and the user may perceive the luminance difference when the display device is viewed at various angles.

It is confirmed that in the light emitting element according to the exemplary embodiment, light extracted to the front direction by the light extraction member 124 is increased. For example, in the light emitting element of the exemplary embodiment, it is confirmed that the light is uniformly dispersed while being scattered by the light extraction member 124 and the difference between the luminance in the front direction and the luminance in the lateral direction is smaller than that of the light emitting element of the comparative embodiment. For example, in the case of the light emitting element according to the exemplary embodiment, when the luminance in the front direction is defined as 100%, a peak luminance in the lateral direction as compared with the luminance in the front direction may be approximately 112%. Therefore, it is confirmed that the difference between the luminance in the front direction and the peak luminance in the lateral direction is reduced, in the light emitting element according to the exemplary embodiment than in the light emitting element according to the comparative embodiment. Accordingly, when the light emitting element according to the exemplary embodiment is used, the difference in the luminance perceived by the user who views the display device 100 at various angles may be minimized.

Therefore, in the light emitting element 120 of the display device 100 according to the exemplary embodiment of the present disclosure, light emitted from the emission layer 122 is scattered in the light extraction member 124 and light which is extracted in the front direction may be increased. Further, the luminance difference between the front direction and the lateral direction may be reduced. Specifically, the light extraction member 124 disposed in the direction perpendicular to one surface of the emission layer 122 scatters light emitted from the emission layer 122 to increase an amount of light extracted to the front direction and reduce the difference between the luminance in the front direction and the luminance in the lateral direction. Accordingly, in the display device 100 according to the exemplary embodiment of the present disclosure, the light extraction member 124 is formed above the light emitting element 120 to reduce the luminance difference according to the viewing angle and improve the display quality of the display device 100.

In the meantime, in the display device 100 according to the exemplary embodiment of the present disclosure, when the light emitting element 120 is manufactured, the plurality of light extraction particles PC is self-assembled in the groove 123G to easily form the light emitting element 120 including the light extraction member 124.

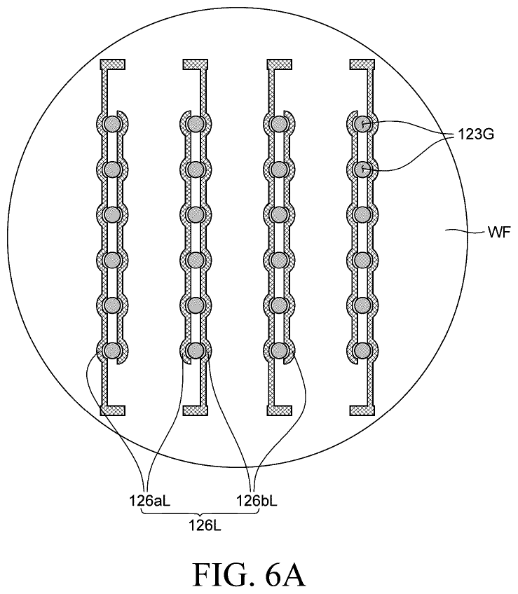

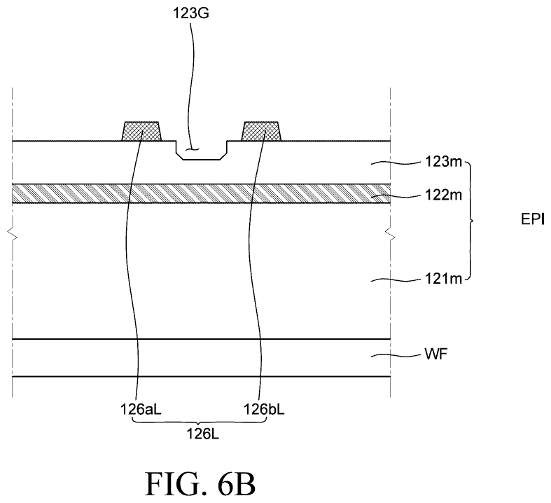

Hereinafter, a method for manufacturing a light emitting element 120 according to an exemplary embodiment of the present disclosure will be described with reference to FIGS. 6A to 10B.

FIGS. 6A to 10B are process diagrams for explaining a method for manufacturing a light emitting element according to an exemplary embodiment of the present disclosure. Specifically, FIGS. 6A, 7A, 8A, 9A, and 10A are plan views of a wafer WF for explaining a manufacturing method of a light emitting element 120 and FIGS. 6B, 7B, 8B, 9B, and 10B are enlarged cross-sectional views of a wafer WF for explaining a manufacturing method of a light emitting element 120.

Referring to FIGS. 6A and 6B, an epi layer EPI is formed on a wafer WF. A plurality of LEDs is grown on the wafer WF and the wafer WF may be formed of various materials according to a material which configures the plurality of LEDs. For example, the wafer WF may be formed of sapphire, gallium nitride (GaN), silicon (Si), or silicon carbide (SiC), but is not limited thereto.

The epi layer EPI is provided to form the plurality of LEDs and includes a first semiconductor material layer 121m, an emission material layer 122m, and a second semiconductor material layer 123m. The first semiconductor material layer 121m is a layer which forms the first semiconductor layer 121, the emission material layer 122m is a layer which forms the emission layer 122, and the second semiconductor material layer 123m is a layer which forms the second semiconductor layer 123.

First, the first semiconductor material layer 121m may be formed by growing a semiconductor crystal on the wafer WF. Next, the emission material layer 122m and the second semiconductor material layer 123m may be formed by growing a semiconductor crystal on the first semiconductor material layer 121m. In this case, the emission material layer 122m may be grown by inheriting the crystallinity of the first semiconductor material layer 121m and the second semiconductor material layer 123m grown on the emission material layer 122m may be grown by inheriting the crystallinity of the emission material layer 122m. Accordingly, the epi layer EPI may be formed by sequentially growing the first semiconductor material layer 121m, the emission material layer 122m, and the second semiconductor material layer 123m on the wafer WF.

The epi layer EPI may be formed on the wafer WF using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Next, the groove 123G is formed in the second semiconductor material layer 123m of the epi layer EPI. In the groove 123G, the light extraction member 124 may be disposed. The plurality of grooves 123G is formed in the second semiconductor material layer 123m and the light extraction particles PC which form the light extraction member 124 may be self-assembled in the plurality of grooves 123G.

Next, a plurality of assembly lines 126L is formed on the epi layer EPI.

The plurality of assembly lines 126L is wiring lines for self-assembling the light extraction particles PC in the plurality of grooves 123G. The plurality of assembly lines 126L is patterned into a plurality of lines in a subsequent process to become a 2-1-th electrode 126a and a 2-2-th electrode 126b of the light emitting element 120. A part of the assembly line 126L adjacent to the plurality of grooves 123G may be formed to have a shape along edges of the plurality of grooves 123G.

The plurality of assembly lines 126L includes a first assembly line 126aL and a second assembly line 126bL. The first assembly line 126aL and the second assembly line 126bL may be spaced apart from each other with the plurality of grooves 123G therebetween. For example, the first assembly line 126aL may be disposed on one side of the plurality of grooves 123G and the second assembly line 126bL may be disposed on the other side of the plurality of grooves 123G. A pad electrode is formed in an end portion of each of the plurality of assembly lines 126L to apply a voltage to the plurality of assembly lines 126L.

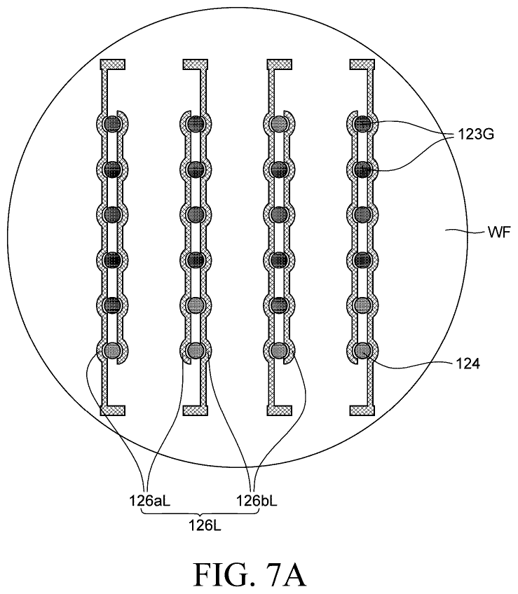

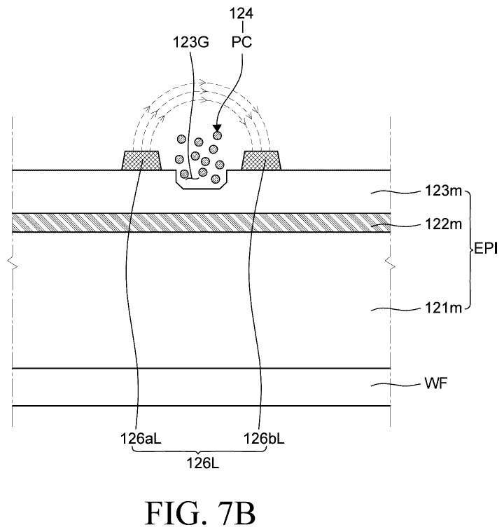

Referring to FIGS. 7A and 7B, a plurality of light extraction particles PC which forms the light extraction member 124 is self-assembled in the plurality of grooves 123G.

A voltage is applied to the plurality of assembly lines 126L to self-assemble the plurality of light extraction particles PC in the plurality of grooves 123G. For example, different AC voltages are applied to the plurality of first assembly lines 126aL and the plurality of second assembly lines 126bL to form an electric field. The plurality of light extraction particles PC may move or may be fixed in a specific direction by dielectrophoresis (DEP), that is, an electric field. Accordingly, the plurality of light extraction particles PC may be self-assembled in the plurality of grooves 123G using the electric field.

In the meantime, when the plurality of light extraction particles PC is self-assembled, the electric field and the magnetic field are used together to perform the self-assembly. For example, the plurality of light extraction particles PC including magnetic particles PC1 may move to the wafer WF using a magnet. The plurality of light extraction particles PC which moves to be adjacent to the wafer WF by the magnet MG may be self-assembled in the groove 123G along the electric field formed between the assembly lines 126L.

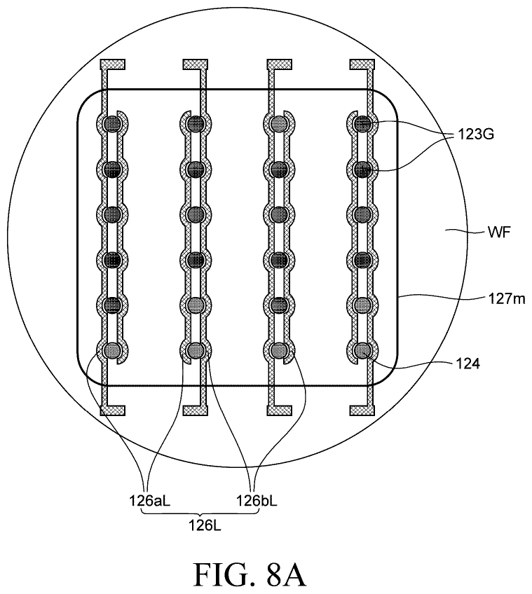

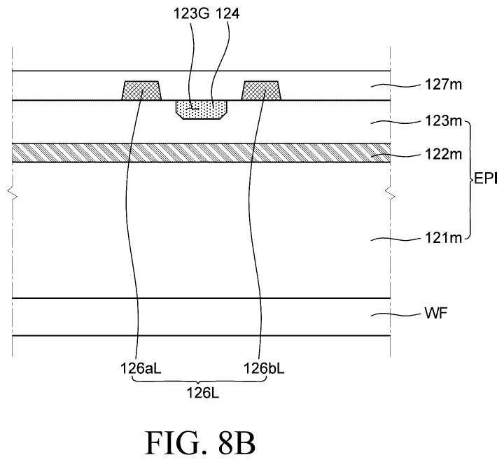

Referring to FIGS. 8A and 8B, an insulating film 127m is formed on the epi layer EPI and the plurality of assembly lines 126L. The insulating film 127m is formed to protect the plurality of light extraction particles PC self-assembled in the groove 123G. The insulating film 127m may be disposed so as to cover the plurality of assembly lines 126L, the plurality of light extraction particles PC, and the second semiconductor material layer 123m.

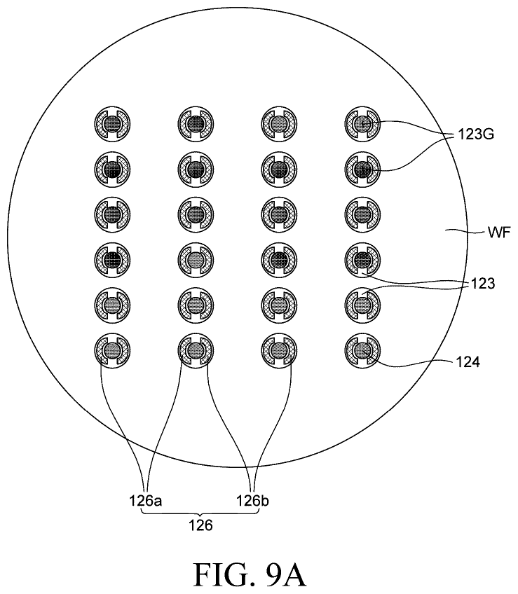

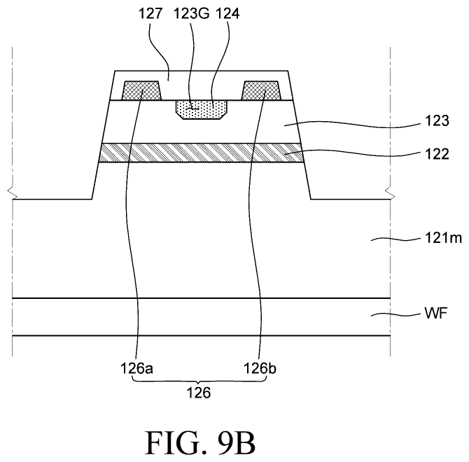

Referring to FIGS. 9A and 9B, the epi layer EPI is subject to the mesa etching to form the first semiconductor layer 121, the emission layer 122, and the second semiconductor layer 123. A second semiconductor material layer 123m, an emission material layer 122m, and a first semiconductor material layer 121m of the epi layer EPI are etched by mesa etching to form the plurality of second semiconductor layers 123, the plurality of emission layers 122, and the plurality of first semiconductor layers 121. The second semiconductor material layer 123m is patterned into a plurality of layers with respect to the plurality of grooves 123G to form a plurality of second semiconductor layers 123. Next, the emission material layer 122m is etched to form the plurality of emission layers 122 below the plurality of second semiconductor layers 123. A part of an upper side of the first semiconductor material layer 121m which is exposed from the plurality of emission layers 122 and the plurality of second semiconductor layers 123 may be partially etched. Accordingly, the epi layer EPI may be formed to have a shape as illustrated in FIG. 9B, by the mesa etching.

During this process, the insulating film 127m and the plurality of assembly lines 126L on the epi layer EPI are also etched to form the plurality of first protection films 127 and the plurality of second electrodes 126. For example, the plurality of assembly lines 126L is etched into a plurality of lines so that the first assembly line 126aL and the second assembly line 126bL remaining on the top surface of the second semiconductor layer 123 may become a 2-1-th electrode 126a and a 2-2-th electrode 126b, respectively. The insulating film 127m is etched during the etching process of the second semiconductor material layer 123m to remain only on the top surface of the second semiconductor layer 123 and serve as the first protection film 127 thereafter.

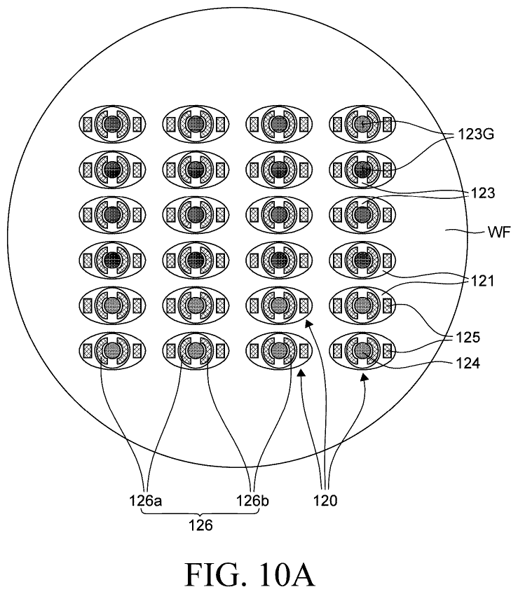

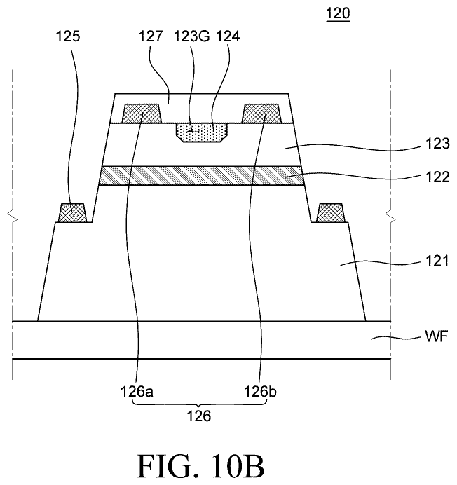

Referring to FIGS. 10A and 10B, the first electrode 125 is formed and the first semiconductor material layer 121m is etched to form the first semiconductor layer 121. The plurality of first electrodes 125 may be formed on the first semiconductor material layer 121m. The first semiconductor material layer 121m is etched to form the plurality of first semiconductor layers 121. Accordingly, the epi layer EPI is separately formed into a plurality of layers to form a plurality of light emitting elements 120 including a first semiconductor layer 121, an emission layer 122, a second semiconductor layer 123, a first electrode 125, a second electrode 126, a light extraction member 124, and a first protection film 127.

At this time, an order of a formation process of the first electrode 125 and a formation process of the first semiconductor layer 121 may vary, and are not limited thereto.

Finally, even though it is not illustrated in the drawing, the second protection film 128 may be formed on the plurality of light emitting elements 120. After completing the formation process of the plurality of light emitting elements 120, the plurality of light emitting elements 120 is separated from the wafer WF and is transferred to a target substrate to form the display device 100.

According to the method for manufacturing a light emitting element 120 according to the exemplary embodiment of the present disclosure, the plurality of light extraction particles PC may be easily disposed in the plurality of grooves 123G by a self-assembly method using an electric field. Specifically, the plurality of grooves 123G and the plurality of assembly lines 126L may be formed on the epi layer EPI. An electric field is formed by applying a voltage to the plurality of assembly lines 126L to self-assemble the plurality of light extraction particles PC in the plurality of grooves 123G. Accordingly, the light extraction particles PC are aligned in the groove 123G to be self-assembled using the assembly line 126L, thereby shortening the process time and suppressing a process failure according to an alignment error of the light extraction particle PC and the groove 123G. The light extraction members 124 of the plurality of light emitting elements 120 may be simultaneously self-assembled using the electric field to achieve the process optimization. Further, the assembly line 126L is etched together with the second semiconductor material layer 123m to be used as the second electrode 126 of the light emitting element 120 so that the formation process of the second electrode 126 of the light emitting element 120 may be simplified.

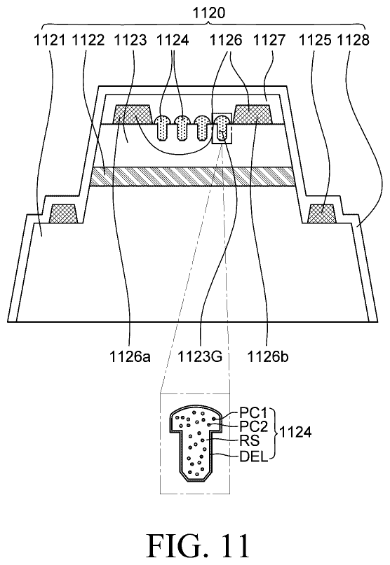

FIG. 11 is an enlarged cross-sectional view of a light emitting element of a display device according to another exemplary embodiment of the present disclosure. A light emitting element 1120 of FIG. 11 is substantially the same as the light emitting element 120 of FIGS. 1 to 10B except for a configuration of a groove 1123G and a light extraction member 1124 so that a redundant description will be omitted.

Referring to FIG. 11, the light emitting element 1120 includes a plurality of grooves 1123G formed in a second semiconductor layer 1123. A plurality of grooves 1123G may be formed in an area between the 2-1-th electrode 1126a and a 2-2-th electrode 1126b on a top surface of the second semiconductor layer 1123.

The light emitting element 1120 includes a light extraction member 1124 formed in each of the plurality of grooves 1123G. At least a part of the light extraction member 1124 may be disposed to protrude to the outside of the groove 1123G. The first protection film 1127 may be disposed so as to cover the plurality of light extraction members 1124 which protrudes to the outside of the groove 1123G. A shape of a part of the light extraction member 1124 which protrudes to the outside of the groove 1123G may have a lens shape.

The light extraction member 1124 may be formed of a micro lens in which a plurality of magnetic particles PC1 and a plurality of scattering particles PC2 are dispersed. After dispersing the plurality of magnetic particles PC1 and the plurality of scattering particles PC2 in a resin RS, the resin RS is hardened to form the micro lens. For example, the resin RS may be an acryl or epoxy-based material, but is not limited thereto. During the self-assembly process of the light extraction member 1124, the micro lens including the plurality of magnetic particles PC1 may easily move to the wafer WF using the magnetic field and the electric field.

The light extraction member 1124 may further include a dielectric film DEL formed on a surface of the micro lens. The dielectric film DEL may be formed of a dielectric material. For example, the dielectric film DEL may include silicon oxide (SiO₂), silicon carbide (SiC), silicon nitride (SiN), or aluminum oxide (Al₂O₃), but is not limited thereto. During the self-assembly process of the plurality of light extraction members 1124, the micro lens including the dielectric film DEL is dielectrically polarized to have polarity and may move or be fixed in a specific direction by an electric field.

The plurality of light extraction members 1124 disposed in the plurality of grooves 1123G may form a micro lens array. Specifically, a part of the light extraction member 1124 which protrudes to the outside of the groove 1123G is configured like a lens to serve as a micro lens array. Accordingly, the light extraction member 1124 which is configured as a micro lens array scatters or reflects light emitted from the emission layer 1122 to uniformly disperse light which is extracted in the front direction and the lateral direction.

Accordingly, the light emitting element 1120 of the display device according to another exemplary embodiment of the present disclosure includes a plurality of light extraction members 1124 configured by a micro lens to reduce a luminance deviation according to a viewing angle of the light emitting element 1120. The light extraction member 1124 may be formed of a micro lens in which scattering particles PC2 and magnetic particles PC1 are dispersed. The plurality of grooves 1123G is formed in the second semiconductor layer 1123 of the light emitting element 1120 and the plurality of light extraction members 1124 is self-assembled in the groove 1123G to form a micro lens array above the light emitting element 1120. The plurality of light extraction members 1124 which serves as a micro lens array scatters light emitted from the emission layer 1122 to reduce the difference in an amount of light emitted to the front direction and the lateral direction. Further, a density of the scattering particles PC2 disposed in each of the plurality of grooves 1123G may be easily adjusted by adjusting an amount of scattering particles PC2 dispersed in the resin RS when the light extraction member 1124 is formed.

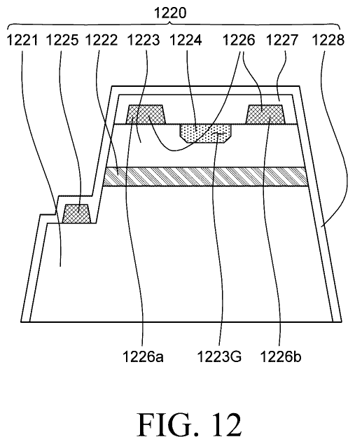

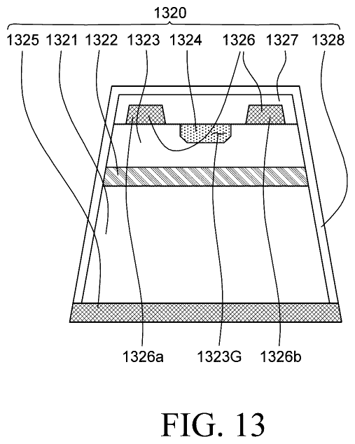

FIG. 12 is an enlarged cross-sectional view of a light emitting element of a display device according to still another exemplary embodiment of the present disclosure. FIG. 13 is an enlarged cross-sectional view of a light emitting element of a display device according to still another exemplary embodiment of the present disclosure. Light emitting elements 1220 and 1320 of FIGS. 12 and 13 are substantially the same as the light emitting element 120 of FIGS. 1 to 10B except for a configuration of light emitting elements 1220 and 1320 so that a redundant description will be omitted.

Referring to FIG. 12, the light emitting element 1220 may be formed as a lateral type. In the lateral type of light emitting element 1220, an emission layer 1222 and a second semiconductor layer 1223 may be sequentially disposed on a first semiconductor layer 1221, a first electrode 1225 may be disposed on a top surface of the first semiconductor layer 1221, and a second electrode 1226 may be disposed on a top surface of the second semiconductor layer 1223. A groove 1223G may be formed in the second semiconductor layer 1223 in an area between one pair of second electrodes 1226 and the light extraction member 1224 may be disposed in the groove 1223G. The light emitting element 1220 may further include a first protection film 1227 which covers the second electrode 1226 and the light extraction member 1224 and a second protection film 1228 which entirely encloses the light emitting element.

Referring to FIG. 13, the light emitting element 1320 may be formed as a vertical type. In the vertical type of light emitting element 1320, an emission layer 1322 and a second semiconductor layer 1323 may be sequentially disposed on a first semiconductor layer 1321, a first electrode 1325 may be disposed on a bottom surface of the first semiconductor layer 1321, and a second electrode 1326 may be disposed on a top surface of the second semiconductor layer 1323. The groove 1323G and the light extraction member 1324 may be disposed between one pair of second electrodes 1326 of the light emitting element 1320. The light emitting element 1320 may further include a first protection film 1327 which covers the second electrode 1326 and the light extraction member 1324 and a second protection film 1328 which entirely encloses the light emitting element.

Referring to FIGS. 12 and 13 together, in each of the light emitting element 1220 with the lateral structure and the light emitting element 1320 with the vertical structure, the grooves 1223G and 1323G, the 2-1-th electrodes 1226a and 1326a, and the 2-2-th electrodes 1226b and 1326b are formed on top surfaces of the second semiconductor layers 1223 and 1323. By doing this, the light extraction members 1224 and 1324 may be self-assembled in the grooves 1223G and 1323G. Accordingly, the grooves 1223G and 1323G, the 2-1-th electrodes 1226a and 1326a, and the 2-2-th electrodes 1226b and 1326b are formed in the light emitting elements 1220 and 1320 with various structures to self-assemble the light extraction members 1224 and 1324 on the light emitting elements 1220 and 1320.

In the meantime, in FIGS. 12 and 13, it is illustrated that the light emitting elements 1220 and 1320 include the light extraction member 124 which is used for the light emitting element 120 of FIGS. 3 and 4. However, a micro lens shaped light extraction member 1124 which has been described with reference to FIG. 11 may be applied to the light emitting elements 1220 and 1320 of FIGS. 12 and 13, but is not limited thereto.

Accordingly, also in various types of light emitting elements 1220 and 1320, the grooves 1223G and 1323G and one pair of second electrodes 1226 and 1326 disposed with the grooves 1223G and 1323G therebetween are formed to easily form the light extraction members 1224 and 1324. Accordingly, the light extraction members 1224 and 1324 which are formed by a self-assembly method may be applied without being limited to the type of light emitting elements 1220 and 1320.

The exemplary embodiments of the present disclosure can also be described as follows:

According to an aspect of the present disclosure, a method for manufacturing a light emitting element includes a step of forming an epi layer having a plurality of grooves on a wafer, a step of forming a plurality of assembly lines on the epi layer, a step of self-assembling a plurality of light extraction particles in each of the plurality of grooves by applying a voltage to the plurality of assembly lines, and a step of forming a plurality of light emitting elements by etching the plurality of assembly lines and the epi layer.

The step of self-assembling a plurality of light extraction particles may be a step of self-assembling the plurality of light extraction particles in the plurality of grooves by forming an electric field by applying the voltage to the plurality of assembly lines.

Each of the plurality of light emitting elements may include a first semiconductor layer, an emission layer on the first semiconductor layer, a second semiconductor layer which is disposed on the emission layer and has at least one groove, among the plurality of grooves, a first electrode which is in contact with the first semiconductor layer, a 2-1-th electrode and a 2-2-th electrode which are in contact with the second semiconductor layer and are spaced apart from each other with the groove therebetween, a light extraction member which is disposed in the at least one groove and is configured by the plurality of light extraction particles, and a first protection film which covers the light extraction member, the 2-1-th electrode, and the 2-2-th electrode.

The plurality of assembly lines may include a first assembly line disposed on one side of each of the plurality of grooves, and a second assembly line which is disposed on the other side of each of the plurality of grooves.

The step of forming a plurality of light emitting elements by etching the plurality of assembly lines and the epi layer may include a step of forming the 2-1-th electrode and the 2-2-th electrode of each of the plurality of light emitting elements by etching the first assembly line and the second assembly line.

The epi layer may include a first semiconductor material layer, an emission material layer, and a second semiconductor material layer which are sequentially laminated, and the step of forming a plurality of light emitting elements by etching the plurality of assembly lines and the epi layer may include a step of forming the first semiconductor layer, the emission layer, and the second semiconductor layer by etching the first semiconductor material layer, the emission material layer, and the second semiconductor material layer of the epi layer.

The method for manufacturing a light emitting element may further include after the step of self-assembling a plurality of light extraction particles, a step of forming an insulating film which covers the plurality of assembly lines, the plurality of light extraction particles, and the epi layer, and the insulating film may be etched together with the epi layer in the step of forming the plurality of light emitting elements by etching the plurality of assembly lines and the epi layer to be formed as the first protection film of each of the plurality of light emitting elements.

Each of the plurality of light extraction particles may include a magnetic particle, and a scattering particle coated on a surface of the magnetic particle, and the plurality of light extraction particles may be configured to move to the wafer by the magnetic particle which reacts to the magnet.

The light extraction member may include a resin in which the plurality of light extraction particles is dispersed, and a dielectric film formed on a surface of the resin, and the plurality of light extraction particles may include a plurality of magnetic particles and a plurality of scattering particles, and the light extraction member may be configured to move to the wafer by the plurality of magnetic particles which reacts to the magnet.

The light extraction member may be a micro lens.

A part of the light extraction member may protrude to an outside of the groove and the light extraction member which protrudes to the outside of the groove is formed with a lens shape.

According to an aspect of the present disclosure, a light emitting element includes a first semiconductor layer, an emission layer on the first semiconductor layer, a second semiconductor layer which is disposed on the emission layer and has one or more grooves therein, a first electrode which is in contact with the first semiconductor layer, one pair of second electrodes disposed on a top surface of the second semiconductor layer, and a light extraction member disposed in the groove.

The pair of second electrodes may be disposed to be spaced apart from each other with the light extraction member therebetween.

The light emitting element may further include a first protection film which covers the light extraction member and the pair of second electrodes.

The light emitting element may further include a second protection film which covers the first protection film, the first semiconductor layer, the second semiconductor layer, and the emission layer.

The light extraction member may include a plurality of light extraction particles and the plurality of light extraction particles may be formed of magnetic particles with scattering particles coated at an outside.

The light extraction member may include a resin, a plurality of magnetic particles dispersed in the resin, and a plurality of scattering particles dispersed in the resin.

The light extraction member may be a micro lens.

A part of the light extraction member may protrude to an outside of the groove and the part of the light extraction member which protrudes to the outside of the groove may be formed with a lens shape.

The light extraction member may further include a dielectric film formed on a surface of the resin.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a light emitting element, comprising:
forming an epi layer having a plurality of grooves on a wafer;
forming a plurality of assembly lines on the epi layer;
self-assembling a plurality of light extraction particles in each of the plurality of grooves by applying a voltage to the plurality of assembly lines; and
forming a plurality of light emitting elements by etching the plurality of assembly lines and the epi layer.

2. The method for manufacturing a light emitting element according to claim 1, wherein the self-assembling a plurality of light extraction particles includes self-assembling the plurality of light extraction particles in the plurality of grooves by forming an electric field by applying the voltage to the plurality of assembly lines.

3. The method for manufacturing a light emitting element according to claim 1, wherein each of the plurality of light emitting elements includes:
a first semiconductor layer;
an emission layer disposed on the first semiconductor layer;
a second semiconductor layer which is disposed on the emission layer and has at least one groove, among the plurality of grooves;
a first electrode which is in contact with the first semiconductor layer;
a 2-1-th electrode and a 2-2-th electrode which are in contact with the second semiconductor layer and are spaced apart from each other with the groove therebetween;
a light extraction member which is disposed in the at least one groove and is configured by the plurality of light extraction particles; and
a first protection film which covers the light extraction member, the 2-1-th electrode, and the 2-2-th electrode.

4. The method for manufacturing a light emitting element according to claim 3, wherein the plurality of assembly lines includes:
a first assembly line disposed on one side of each of the plurality of grooves; and
a second assembly line which is disposed on the other side of each of the plurality of grooves.

5. The method for manufacturing a light emitting element according to claim 4, wherein the forming a plurality of light emitting elements by etching the plurality of assembly lines and the epi layer includes:
forming the 2-1-th electrode and the 2-2-th electrode of each of the plurality of light emitting elements by etching the first assembly line and the second assembly line.

6. The method for manufacturing a light emitting element according to claim 3, wherein the epi layer includes a first semiconductor material layer, an emission material layer, and a second semiconductor material layer which are sequentially laminated, and
wherein the forming a plurality of light emitting elements by etching the plurality of assembly lines and the epi layer includes:
forming the first semiconductor layer, the emission layer, and the second semiconductor layer by etching the first semiconductor material layer, the emission material layer, and the second semiconductor material layer of the epi layer.

7. The method for manufacturing a light emitting element according to claim 3, further comprising:
after the self-assembling of a plurality of light extraction particles,
forming an insulating film which covers the plurality of assembly lines, the plurality of light extraction particles, and the epi layer,
wherein the insulating film is etched together with the epi layer in the step of forming the plurality of light emitting elements by etching the plurality of assembly lines and the epi layer to be formed as the first protection film of each of the plurality of light emitting elements.

8. The method for manufacturing a light emitting element according to claim 3, wherein each of the plurality of light extraction particles includes:
a magnetic particle; and
a scattering particle coated on a surface of the magnetic particle, and
wherein the plurality of light extraction particles is configured to move to the wafer by the magnetic particle which reacts to a magnet.

9. The method for manufacturing a light emitting element according to claim 3, wherein the light extraction member includes:
a resin in which the plurality of light extraction particles is dispersed; and
a dielectric film formed on a surface of the resin, and
the plurality of light extraction particles includes a plurality of magnetic particles and a plurality of scattering particles, and
the light extraction member is configured to move to the wafer by the plurality of magnetic particles which reacts to a magnet.

10. The method for manufacturing a light emitting element according to claim 9, wherein the light extraction member is a micro lens.

11. The method for manufacturing a light emitting element according to claim 9, wherein a part of the light extraction member protrudes to an outside of the groove and the light extraction member which protrudes to the outside of the groove is formed with a lens shape.

12. A light emitting element, comprising:
a first semiconductor layer;
an emission layer disposed on the first semiconductor layer;
a second semiconductor layer which is disposed on the emission layer and has one or more grooves therein;
a first electrode which is in contact with the first semiconductor layer;
one pair of second electrodes disposed on a top surface of the second semiconductor layer; and
a light extraction member disposed in one of the grooves.

13. The light emitting element according to claim 12, wherein the pair of second electrodes is disposed to be spaced apart from each other with the light extraction member therebetween.

14. The light emitting element according to claim 12, further comprising:
a first protection film which covers the light extraction member and the pair of second electrodes.

15. The light emitting element according to claim 14, further comprising:
a second protection film which covers the first protection film, the first semiconductor layer, the second semiconductor layer, and the emission layer.

16. The light emitting element according to claim 12, wherein the light extraction member includes a plurality of light extraction particles and the plurality of light extraction particles is formed of magnetic particles with scattering particles coated at an outside.

17. The light emitting element according to claim 12, wherein the light extraction member includes:
a resin;
a plurality of magnetic particles dispersed in the resin; and
a plurality of scattering particles dispersed in the resin.

18. The light emitting element according to claim 17, wherein the light extraction member is a micro lens.

19. The light emitting element according to claim 17, wherein a part of the light extraction member protrudes to an outside of the groove and the part of the light extraction member which protrudes to the outside of the groove is formed with a lens shape.

20. The light emitting element according to claim 17, wherein the light extraction member further includes a dielectric film formed on a surface of the resin.
